(19) United States
(12) Patent Application Publication
(10) Pub. No.: US 2017/0114462 A1
(43) Pub. Date: Apr. 27, 2017

(54) HIGH PRODUCTIVITY PECVD TOOL FOR WAFER PROCESSING OF SEMICONDUCTOR MANUFACTURING

(71) Applicant: Applied Materials, Inc., Santa Clara, CA (US)

(72) Inventors: Lin ZHANG, San Jose, CA (US); Xuesong LU, Santa Clara, CA (US); Andrew V. LE, San Jose, CA (US); Zheng YUAN, Santa Clara, CA (US); Jang Seok OH, Suwon (KR); Joseph Jamil FARAH, Hollister, CA (US); Rongping WANG, Cupertino, CA (US)

(21) Appl. No.: 15/290,029

(22) Filed: Oct. 11, 2016

Related U.S. Application Data
(60) Provisional application No. 62/277,719, filed on Jan. 12, 2016.
(60) Provisional application No. 62/246,292, filed on Oct. 26, 2015.

(51) Int. Cl. C23C 16/455; C23C 16/50; C23C 16/458; H01L 21/67

(52) U.S. Cl. CPC C23C 16/45565; H01L 21/67196; H01L 21/67201; H01L 21/67161; C23C 16/50; C23C 16/458

(57) ABSTRACT

Embodiments of the present disclosure generally relate to a cluster tool for processing semiconductor substrates. In one embodiment, a cluster tool includes a plurality of process chambers connected to a transfer chamber and each process chamber may simultaneously process four or more substrates. In order to reduce cost, each process chamber includes a substrate support for supporting four or more substrates, single showerhead disposed over the substrate support, and a single radio frequency power source electrically coupled to the showerhead. The showerhead may include a first surface facing the substrate support and a second surface opposite the first surface. A plurality of gas passages may be formed in the showerhead extending from the first surface to the second surface. Process uniformity is improved by increasing the density of the gas passages from the center of the showerhead to the edge of the showerhead.

### CROSS-REFERENCE TO RELATED APPLICATIONS

This application claims priority to U.S. Provisional Patent Application Ser. No. 62/246,292, filed on Oct. 26, 2015 and U.S. Provisional Patent Application Ser. No. 62/277,719, filed on Jan. 12, 2016, which herein are incorporated by reference.

### BACKGROUND

Field

Embodiments of the present disclosure generally relate to a cluster tool for processing semiconductor substrates.

Description of the Related Art

Substrate throughput in semiconductor processing is always a challenge. If technology is to advance, semiconductor substrates continually need to be processed efficiently. Cluster tools have developed as an effective means for processing multiple substrates simultaneously without breaking vacuum. Instead of processing a single substrate and then exposing the substrate to atmosphere during transfer to another chamber, multiple process chambers can be connected to a common transfer chamber so that when a process is complete on the substrate in one process chamber, the substrate can be moved, while still under vacuum, to another process chamber that is coupled to the same transfer chamber.

To further improve throughput and reduce cost, each process chamber may be able to process more than one substrate at once, such as two substrates. However, uniformity may become an issue when there is more than one substrate to be processed at once in a process chamber.

Therefore, an improved cluster tool is needed for increasing throughput, reducing cost, and maintaining process uniformity.

### SUMMARY

Embodiments of the present disclosure generally relate to a cluster tool for processing semiconductor substrates. In one embodiment, a cluster tool includes a plurality of process chambers connected to a transfer chamber and each process chamber may simultaneously process four or more substrates. In order to reduce cost, each process chamber includes a substrate support for supporting four or more substrates, single showerhead disposed over the substrate support, and a single radio frequency power source electrically coupled to the showerhead. The showerhead may include a first surface facing the substrate support and a second surface opposite the first surface. A plurality of gas passages may be formed in the showerhead extending from the first surface to the second surface. Process uniformity is improved by increasing the density of the gas passages from the center of the showerhead to the edge of the showerhead.

In another embodiment, a cluster tool includes a transfer chamber, a loadlock chamber coupled to the transfer chamber, and a plurality of process chambers coupled to the transfer chamber. Each process chamber of the plurality of process chambers includes a chamber wall, and a substrate support assembly disposed within the chamber wall. The substrate support assembly includes four or more substrate supports. The process chamber further includes a showerhead disposed within the chamber wall, and the showerhead is disposed over the four or more substrate supports.

In another embodiment, a cluster tool includes a transfer chamber, a loadlock chamber coupled to the transfer chamber, and a plurality of process chambers coupled to the transfer chamber. Each process chamber of the plurality of process chambers includes a chamber wall, and a substrate support assembly disposed within the chamber wall. The substrate support assembly includes four or more substrate supports. The process chamber further includes a showerhead disposed within the chamber wall. The showerhead includes a first surface facing the substrate support assembly, and the first surface has a curvature.

In another embodiment, a cluster tool includes a transfer chamber, a loadlock chamber coupled to the transfer chamber, and a plurality of process chambers coupled to the transfer chamber. Each process chamber of the plurality of process chambers includes a chamber wall, and a substrate support assembly disposed within the chamber wall. The substrate support assembly includes four or more substrate supports. The process chamber further includes a showerhead disposed within the chamber wall. The showerhead includes a first surface facing the substrate support assembly, a second surface opposite the first surface, and a plurality of gas passages extending from the first surface to the second surface. Each gas passage of the plurality of gas passages includes a first bore, an orifice hole coupled to the first bore, and a second bore coupled to the orifice hole.

In another embodiment, a cluster tool includes a transfer chamber, a loadlock chamber coupled to the transfer chamber, and a plurality of process chambers coupled to the transfer chamber. Each process chamber of the plurality of process chambers includes a chamber wall, and a substrate support assembly disposed within the chamber wall. The substrate support assembly includes four or more substrate supports. The process chamber further includes a showerhead disposed within the chamber wall. The showerhead includes a first surface facing the substrate support assembly, and the first surface has a curvature. Each process chamber further includes a lid, a matching network disposed over the lid, a backing plate coupled to the showerhead, and a flexible radio frequency feed extending from the matching network to the backing plate. The flexible radio frequency feed is angled with respect to a vertical axis of the process chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1D schematically illustrate a cluster tool according to embodiments described herein.

FIGS. 2A-2D schematically illustrate a process chamber according to embodiments described herein.

FIG. 3 is a schematically cross sectional view of a process chamber according to embodiments described herein.

FIG. 4 is a partial cross sectional side view of a showerhead according to embodiments described herein.

FIGS. 5A-5D are schematic cross sectional side views of a portion of the showerhead according to embodiments described herein.

FIGS. 6A-6F are schematic cross sectional side views of a gas passage according to various embodiments described herein.

FIG. 7 is a schematic bottom view of the showerhead according to embodiments described herein.

FIGS. 8A-8C are schematic cross sectional side views of the showerhead according to various embodiments described herein.

FIG. 9 is a schematic cross sectional view of a process chamber according to embodiments described herein.

FIGS. 10A-10B are schematic top views of a backing plate according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a cluster tool for processing semiconductor substrates. In one embodiment, a cluster tool includes a plurality of process chambers connected to a transfer chamber and each process chamber may simultaneously process four or more substrates. In order to reduce cost, each process chamber includes a substrate support for supporting four or more substrates, single showerhead disposed over the substrate support, and a single radio frequency power source electrically coupled to the showerhead. The showerhead may include a first surface facing the substrate support and a second surface opposite the first surface. A plurality of gas passages may be formed in the showerhead extending from the first surface to the second surface. Process uniformity is improved by increasing the density of the gas passages from the center of the showerhead to the edge of the showerhead.

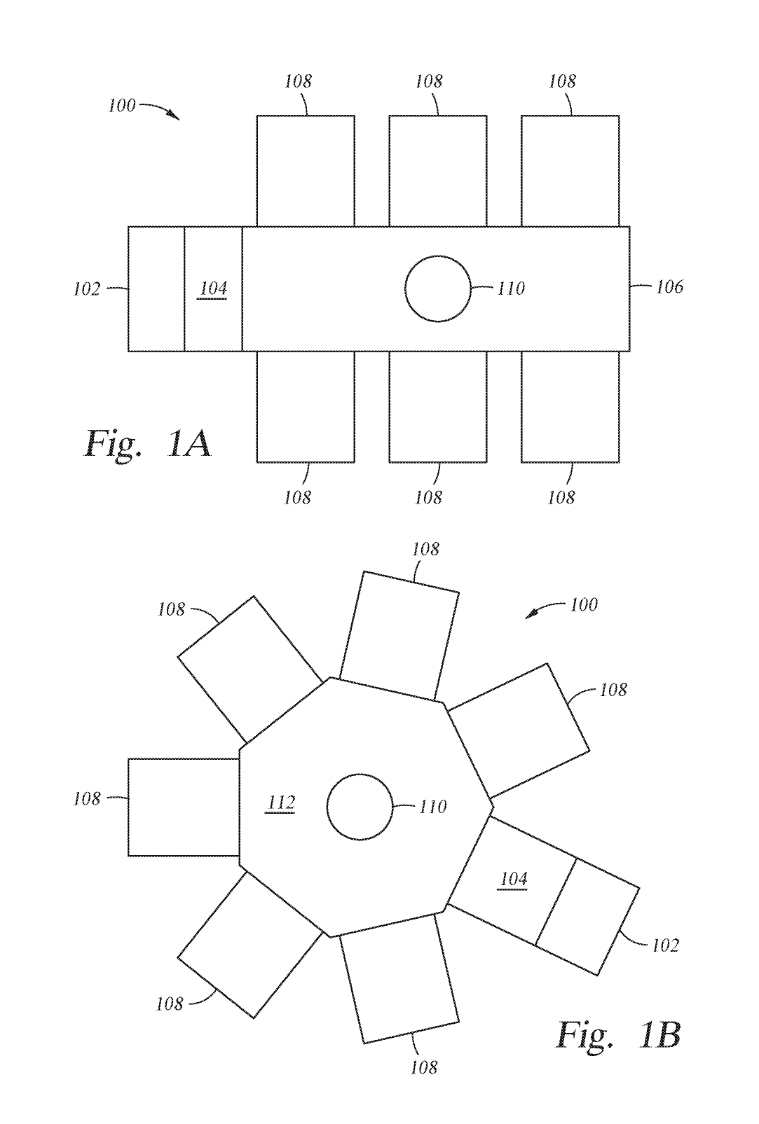

FIGS. 1A-1D schematically illustrate a cluster tool 100 according to one embodiment described herein. As shown in FIG. 1A, the cluster tool 100 may include a factory interface 102, a loadlock chamber 104 coupled to the factory interface 102, a transfer chamber 106 coupled to the loadlock chamber 104, and a plurality of process chambers 108 coupled to the transfer chamber 106. A robot 110 may be disposed in the transfer chamber 106 for transferring substrates from the loadlock chamber 104 to the process chambers 108, or vice versa. The transfer chamber 106 may be rectangular, as shown in FIG. 1A, and six process chambers 108 are coupled to the transfer chamber 106. In some embodiments, more than six process chambers 108 are coupled to the transfer chamber 106.

FIG. 1B schematically illustrates the cluster tool 100 according to another embodiment. Instead of the rectangular transfer chamber 106, the cluster tool 100 includes a heptagonal transfer chamber 112, as shown in FIG. 1B. Six process chambers 108 and the loadlock chamber 104 are each coupled to a side of the heptagonal transfer chamber 112. In some embodiments, the transfer chamber 112 may include more sides for additional process chambers 108 to be coupled thereto. The process chambers 108 shown in FIGS. 1A and 1B are rectangular or square. In some embodiments, the process chambers may be non-rectangular, such as circular. FIG. 1C schematically illustrates the cluster tool 100 including a plurality of non-rectangular process chambers 114 coupled to the transfer chamber 106. In order to be properly coupled to the transfer chamber 106, an adaptor 116 may be utilized between each process chamber 114 and the transfer chamber 106. FIG. 1D schematically illustrates the cluster tool 100 including the plurality of non-rectangular process chambers 114 coupled to the transfer chamber 112. Again adaptors 116 are utilized to couple process chambers 114 to the transfer chamber 112. The cluster tool 100 as shown in FIGS. 1A, 1B, 1C, 1D includes one loadlock chamber 104. Compared to a conventional cluster tool that includes more than one loadlock chambers, cost of the cluster tool 100 having one loadlock chamber 104 is reduced.

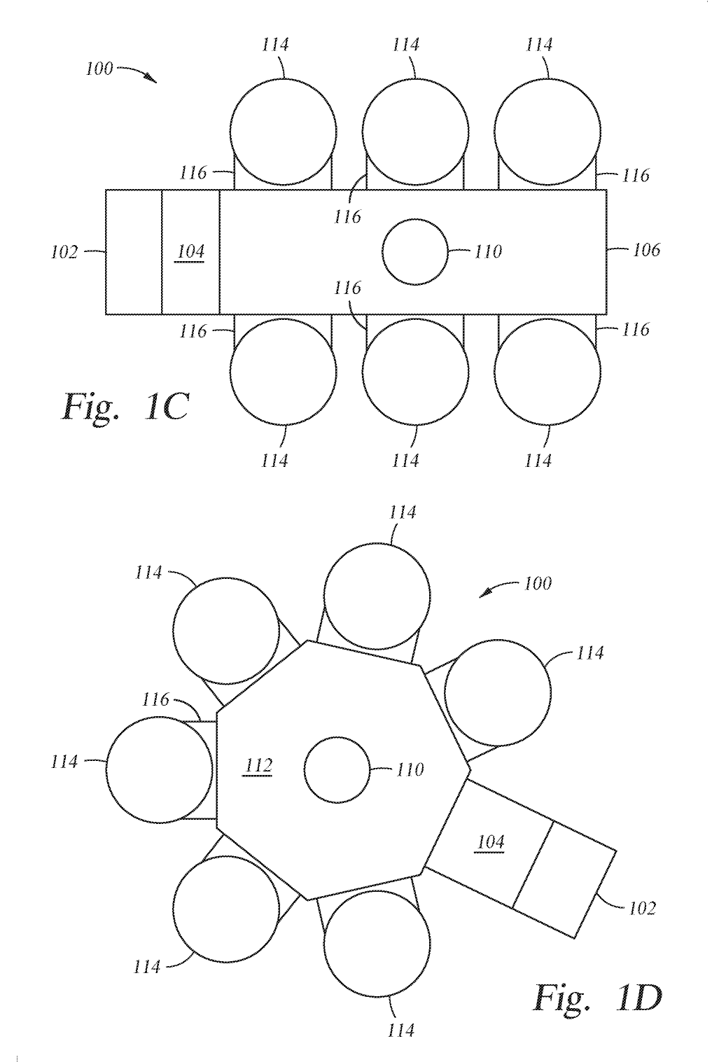

In order to increase throughput, six or more process chambers 108/114 are coupled to a transfer chamber, and each process chamber 108/114 can process four or more substrates. FIGS. 2A and 2B schematically illustrate the process chamber 108/114 according to embodiments described herein. As shown in FIG. 2A, the process chamber 108 is rectangular or square and has chamber walls 202. Disposed within the chamber 108 is a substrate support assembly 204. The substrate support assembly 204 may include four or more substrate supports 206, such as nine substrate supports 206. Each substrate support 206 is configured to support a substrate 208. During operation, each substrate support 206 may be rotating in order to rotate the substrate 208 disposed thereon. The rotation of the substrate support 206 may be a continuous rotation in one direction, or oscillating in opposite directions, such as changing rotation direction after rotating 180 degrees. In one embodiment, the process chamber 108 is a deposition chamber for depositing oxide/nitride or oxide/polycrystalline silicon film stack. The rotation of the substrate supports 206 can improve thickness uniformity of the deposited film stack. In some embodiments, the substrate support assembly 204 may be heated to an elevated temperature, such as up to 700 degrees Celsius, for high temperature processes. Thus, the substrate support assembly 204 may be made of a material that can sustain high temperature regime, such as AlN, Al₂O₃, or graphite with ceramic coating. The substrate support assembly 204 may be coated with a material that can withstand plasma, such as fluorine containing plasma. The coating material may be any suitable material, such as AlO, Y₂O₃, YAlO, or AsMy.

FIG. 2B schematically illustrates the process chamber 114 according to embodiments described herein. The process chamber 114 includes a circular substrate support assembly 210. The substrate support assembly 210 may include four or more substrate supports 212, such as nine substrate supports 212. Each substrate support 212 is configured to support a substrate 208. The substrate support assembly 210 may be rotated during loading and unloading of the substrates 208 and during operation, such as deposition of oxide/nitride film stack. Again each substrate support 212 may be rotating in order to rotate the substrate 208 disposed thereon. The rotation of the substrate support 212 may be a continuous rotation in one direction, or oscillating in opposite directions, such as changing rotation direction after rotating 180 degrees. The rotation of the substrate support assembly 210 and the substrate supports 212 can improve film property uniformity, such as thickness uniformity. During loading and unloading of the substrates 208, the substrates 208 may be loaded/unloaded one at a time or two at a time. The substrate support assembly 210 may be rotated between loading/unloading of one or two substrates 208.

FIG. 2C schematically illustrates the process chamber 108 according to another embodiment described herein. Disposed within the chamber wall (not shown) is a substrate support assembly 214. The substrate support assembly 214 may include a main support 215 and four or more substrate supports 216, such as nine substrate supports 216. Each substrate support 216 is configured to support a substrate 208. A gap 218 may be formed between each substrate support 216 and the main support 215. The process chamber 108 may include a pump 220 located below the substrate support assembly 214 and may be located at the center relative to the substrate support assembly 214. Process gases may flow through the gaps 218 to the pump 220. Because of the pump 220 is located below the center of the substrate support assembly 214, process gas flows through the gaps 218 are uniform (i.e., same gas flow rate through each gap 218). As a result of having the gaps 218, chamber boundary asymmetry induced process gas flow non-uniformity over the substrates 208 is eliminated or minimized. Again, each substrate support 216 may be rotating during operation in order to rotate the substrate 208 disposed thereon. The rotation of the substrate support 216 may be a continuous rotation in one direction, or oscillating in opposite directions, such as changing rotation direction after rotating 180 degrees. In some embodiments, each substrate support 216 may be heated to an elevated temperature, such as up to 700 degrees Celsius, for high temperature processes. Thus, the substrate support 216 may be made of a material that can sustain high temperature regime, such as AlN, Al₂O₃ or graphite with ceramic coating. The substrate supports 216 may be coated with a material that can withstand plasma, such as fluorine containing plasma. The coating material may be any suitable material, such as AlO, Y₂O₃, YAlO, or AsMy.

FIG. 2D schematically illustrates the process chamber 114 according to another embodiment described herein. The process chamber 114 includes a circular substrate support assembly 222. The substrate support assembly 222 may include a main support 224 and four or more substrate supports 226, such as nine substrate supports 226. Each substrate support 226 is configured to support a substrate 208. A gap 228 may be formed between each substrate support 226 and the main support 224. The process chamber 114 may include a pump 230 located below the substrate support assembly 222 and may be located at the center relative to the substrate support assembly 222. Process gases may flow through the gaps 228 to the pump 230. Because of the pump 230 is located below the center of the substrate support assembly 222, process gas flows through the gaps 228 are uniform (i.e., same gas flow rate through each gap 228). As a result of having the gaps 228, chamber boundary asymmetry induced process gas flow non-uniformity over the substrates 208 is eliminated or minimized. The substrate supports 226 may be rotated during operation, such as deposition of oxide/nitride film stack, in order to rotate the substrate 208 disposed thereon. The rotation of the substrate support 226 may be a continuous rotation in one direction, or oscillating in opposite directions, such as changing rotation direction after rotating 180 degrees. In some embodiments, each substrate support 226 may be heated to an elevated temperature, such as up to 700 degrees Celsius, for high temperature processes. Thus, the substrate support 226 may be made of a material that can sustain high temperature regime, such as AlN or graphite with ceramic coating. The substrate supports 226 may be coated with a material that can withstand plasma, such as fluorine containing plasma. The coating material may be any suitable material, such as AlO, Y₂O₃, YAlO, or AsMy.

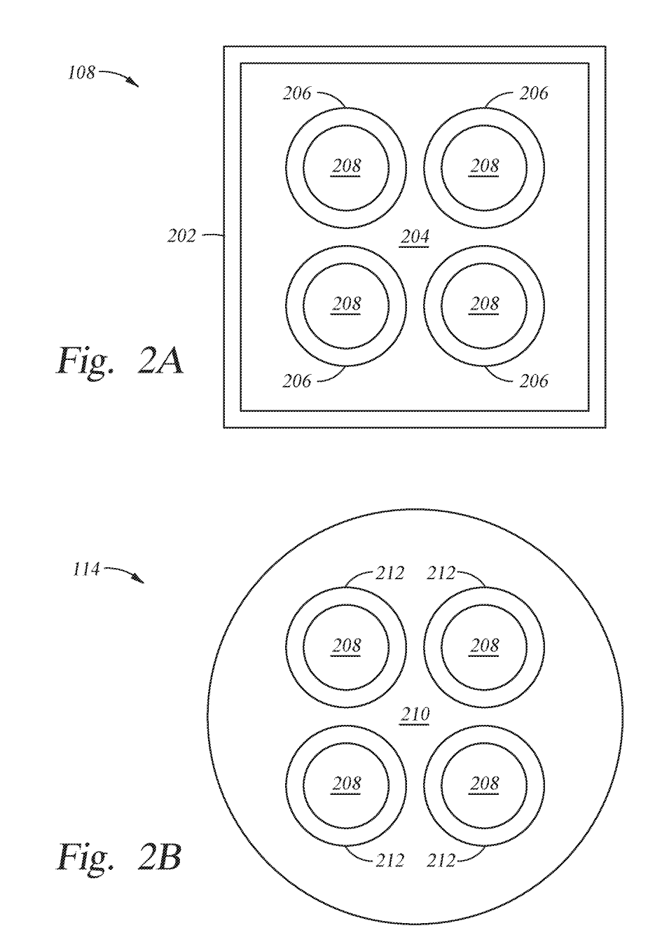

FIG. 3 is a schematically cross sectional view of a process chamber 300 according to embodiments described herein. The process chamber 300 may be the process chamber 108 or the process chamber 114 shown in FIGS. 2A and 2B. The process chamber 300 may be a plasma enhanced chemical vapor deposition (PECVD) chamber that is utilized to deposit dielectric film stacks, such as a stack with alternating oxide and nitride layers or a stack with alternating oxide and polycrystalline silicon layers. As shown in FIG. 3, the process chamber 300 includes a chamber wall 302, a substrate support assembly 304 disposed within the chamber wall 302, and a showerhead 306 disposed within the chamber wall 302. The substrate support assembly 304 may be the same as the substrate support assembly 204, the substrate support assembly 210, the substrate support assembly 214, or the substrate support assembly 222 shown in FIG. 2A, 2B, 2C or 2D, respectively. Four or more substrates 208 may be disposed on the substrate supports 206/212/216/226 of the substrate support assembly 304. In order to reduce cost, a single showerhead 306 is used for processing four substrates 208, and a single RF power source 308 is coupled to the showerhead 306. The showerhead 306 includes a first surface 314 facing the substrate support assembly 304 and a second surface 316 opposite the first surface 314. The showerhead 306 may cover the substrate support assembly 304, so the four or more substrate supports 206/212/216/226 are covered by the single showerhead 306. In other words, the four or more substrate supports 206/212/216/226 may be directly under the single showerhead 306. A gas source 310 may be coupled to the showerhead 306 for delivering one or more process gases into the process chamber 300. A remote plasma source 312 may be also coupled to the showerhead 306 for delivering a cleaning agent, such as dissociated fluorine, into the process chamber 300 to remove deposition by-products and films from process chamber hardware, including the showerhead 306.

The showerhead 306 is typically fabricated from stainless steel, aluminum (Al), anodized aluminum, nickel (Ni) or other RF conductive material. The showerhead 306 could be cast, brazed, forged, hot iso-statically pressed or sintered. The showerhead 306 could be circular or polygonal, such as rectangular or square.

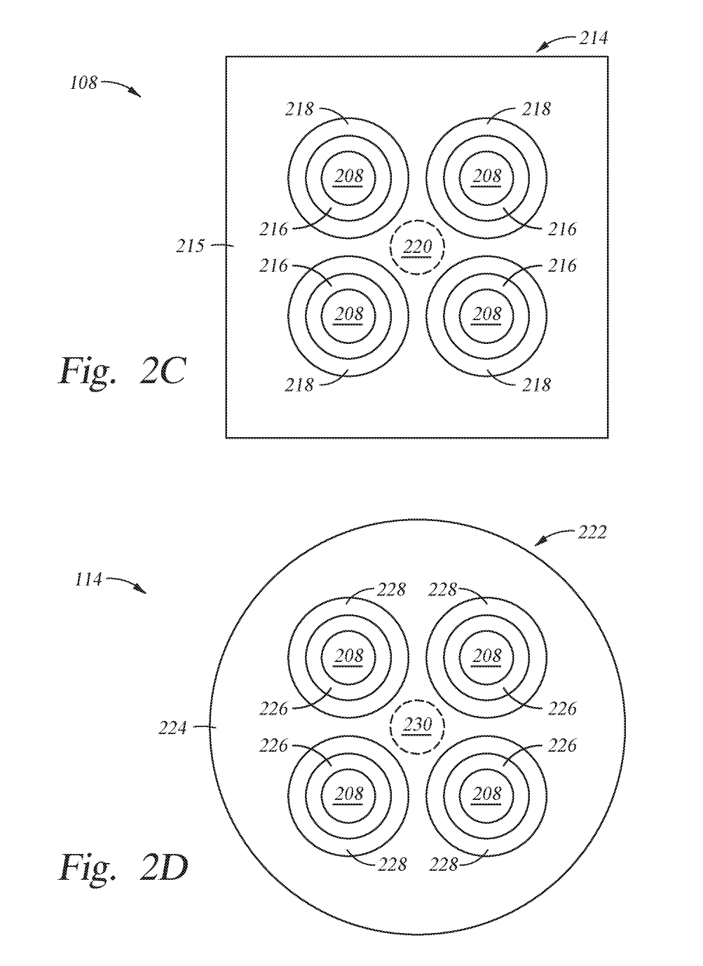

FIG. 4 is a partial cross sectional side view of the showerhead 306 according to embodiments described herein. The showerhead 306 includes the first surface 314 facing the substrate support assembly 304 and the second surface 316 opposite the first surface 314. A plurality of gas passages 402 may be formed in the showerhead 306 extending from the first surface 314 to the second surface 316. Each gas passage 402 is defined by a first bore 410 coupled by an orifice hole 414 to a second bore 412 that combine to form a fluid path through the showerhead 306. The first bore 410 extends a first depth 430 from the second surface 316 of the showerhead 306 to a bottom 418. The bottom 418 of the first bore 410 may be tapered, beveled, chamfered or rounded to minimize the flow restriction as gases flow from the first bore 410 into the orifice hole 414. The first bore 410 generally has a diameter of about 0.093 to about 0.218 inches, and in one embodiment is about 0.156 inches.

The second bore 412 is formed in the showerhead 306 and extends from the first surface 314 to a depth 432 of about 0.10 inch to about 2.0 inches. In one embodiment, the depth 432 is between about 0.1 inch and about 1.0 inch. The diameter 436 of the second bore 412 is generally about 0.1 inch to about 1.0 inch and may be flared at an angle 416 of about 10 degrees to about 50 degrees. In one embodiment, the diameter 436 is between about 0.1 inch to about 0.5 inch and the flaring angle 416 is between 20 degrees to about 40 degrees. The surface of the second bore 412 is between about 0.05 inch² to about 10 inch², such as between about 0.05 inch² to about 5 inch². The diameter of second bore 412 refers to the diameter at the first surface 314. The distances 480 between rims 482 of adjacent second bores 412 are between about 0 inch and about 0.6 inch, such as between about 0 inch and about 0.4 inch. The diameter of the first bore 410 is usually, but not limited to, being at least equal to or smaller than the diameter of the second bore 412. A bottom 420 of the second bore 412 may be tapered, beveled, chamfered or rounded to minimize the pressure loss of gases flowing out from the orifice hole 414 and into the second bore 412.

The orifice hole 414 generally couples the bottom 418 of the first bore 410 and the bottom 420 of the second bore 412. The orifice hole 414 generally has a diameter of about 0.01 inch to about 0.3 inch, such as about 0.01 inch to about 0.1 inch, and typically has a length 434 of about 0.02 inch to about 1.0 inch, such as about 0.02 inch to about 0.5 inch. The length 434 and diameter (or other geometric attribute) of the orifice hole 414 is the primary source of back pressure in a region between the showerhead 306 and a chamber lid which promotes even distribution of gas across the second surface 316 of the showerhead 306. The orifice hole 414 is typically configured uniformly among the plurality of gas passages 402; however, the restriction through the orifice hole 414 may be configured differently among the gas passages 402 to promote more gas flow through one area of the showerhead 306 relative to another area. For example, the orifice hole 414 may have a larger diameter and/or a shorter length 434 in those gas passages 402, of the showerhead 306, closer to the chamber wall 302 of the process chamber 300 so that more gas flows through the edges of the showerhead 306. When processing four substrates 208 simultaneously in the process chamber 300, the showerhead 306 having the first bore 410, the second bore 412 and the orifice hole 414 can optimize gas delivery to each substrate 208 and optimize plasma generation and distribution.

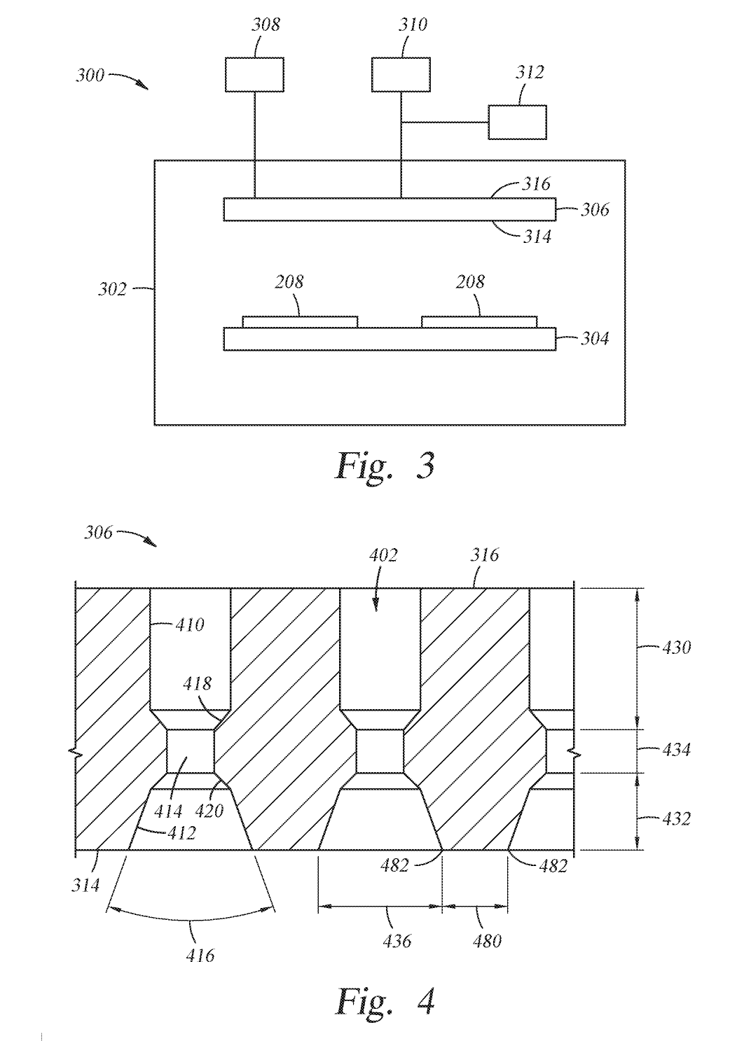

The design of the gas passages 402 can also improve film thickness and film property uniformities. FIGS. 5A-5D are schematic cross sectional side views of a portion of the showerhead 306 according to embodiments described herein. The volume of second bore 412 can be changed by varying the diameter “D” (or diameter 436 in FIG. 4), the depth “d” (or length 432 in FIG. 4) and the flaring angle “a” (or flaring angle 416 of FIG. 4), as shown in FIG. 5A. Changing the diameter, depth and/or the flaring angle would also change the surface area of the second bore 412. By reducing the bore depth, the diameter, the flaring angle, or a combination of these three parameters from edge to center of the showerhead 306, the plasma density could be reduced in the center region of the substrate support assembly 304, at which no substrate 208 is present. Reducing the depth, diameter, and/or flaring angle of the second bore 412 also reduces the surface area of the second bore 412. FIGS. 5B, 5C and 5D show three gas passage designs that are arranged on a showerhead 306. FIGS. 5B, 5C and 5D illustrate designs having the same bore diameter, but the bore depth and total bore surface areas are the largest for FIG. 5B design and the smallest for FIG. 5D design. The bore flaring angles have been changed to match the final bore diameter. The bore depth for FIG. 5B is 0.7 inch, the bore depth for FIG. 5C is 0.5 inch, and the bore depth for FIG. 5D is 0.325 inch. In one embodiment, the showerhead 306 includes a first plurality of gas passages 402 as shown in FIG. 5D located in a center region, a second plurality of gas passages 402 as shown in FIG. 5C surrounding the first plurality of the gas passages 402, and a third plurality of gas passages as shown in FIG. 5B surrounding the second plurality of the gas passages 402.

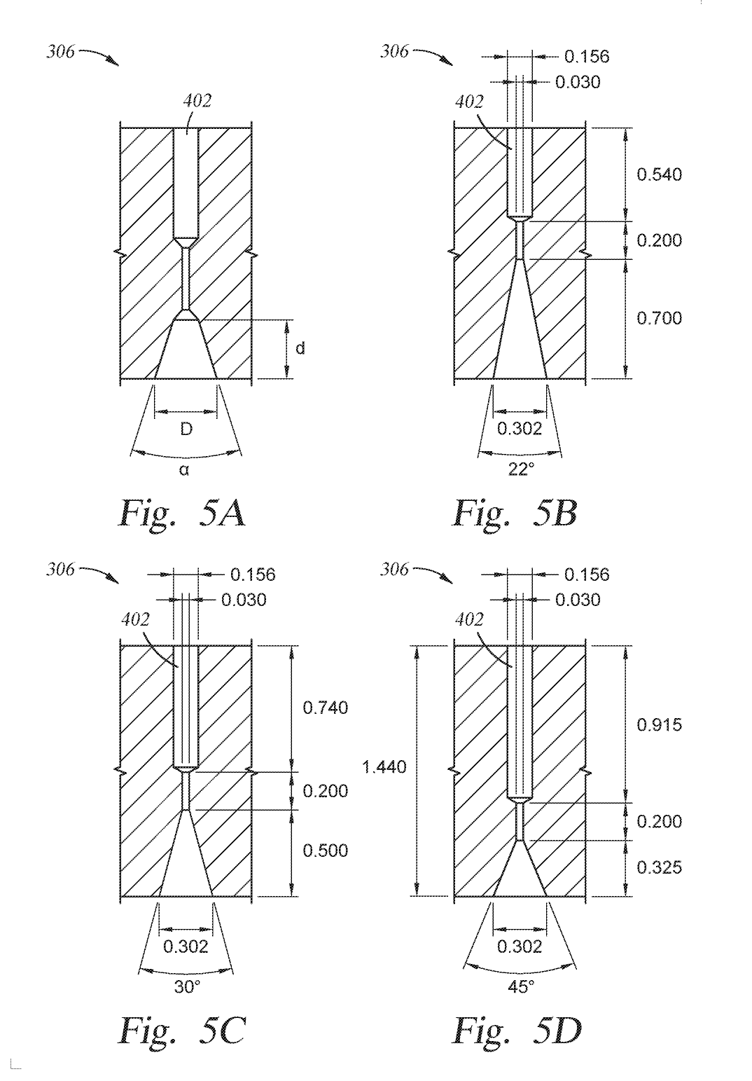

FIGS. 6A-6F are schematic cross sectional side view of the gas passage 402 according to various embodiments described herein. Each gas passage 402 may include the second bore 412, and the various designs of the second bore 412 are illustrated in FIGS. 6A-6F. The gas passage 402 having the second bore 412 as shown in FIGS. 5A-5D and 6A-6F helps improving process uniformity and film thickness and film properties uniformities.

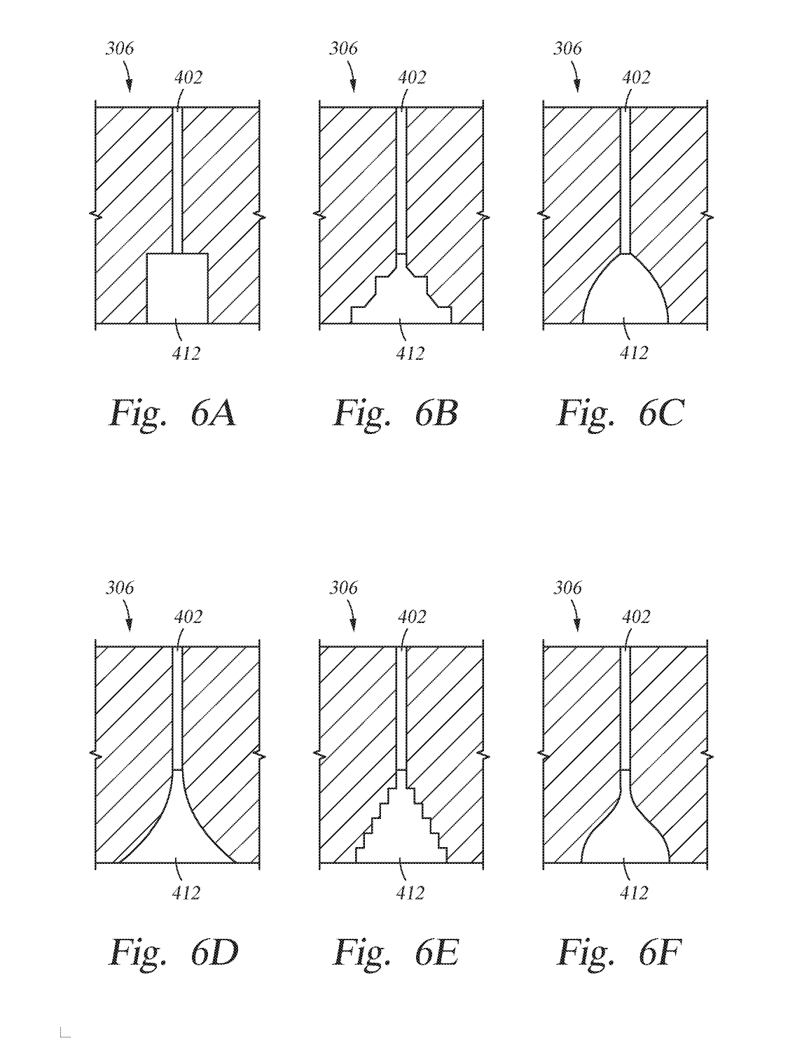

In order to improve film deposition thickness and property uniformities is to change the gas passages 402 density across the showerhead 306, while keeping the diameters of the second bores 412 of the gas passages 402 identical. The density of gas passages 402 is calculated by dividing the total surface of opening of the second bores 412 at the first surface 314 by the total surface of the first surface 314 of the showerhead 306 in the measured region. The density of the gas passages 402 can be varied from about 10% to about 100%, and preferably varied from 30% to about 100%. The gas passages 402 density should be lowered in the inner region, compared to the outer region, to reduce the plasma density in the inner region. The density changes from the inner region to the outer region should be gradual and smooth to ensure uniform and smooth deposition and film property profiles. FIG. 7 shows the gradual change of gas passage 402 density from low in the center (region A) to high at the edge (region B). The lower density of gas passages 402 in the center region would reduce the plasma density in the center region. The arrangement of the gas passages 402 in FIG. 7 is merely used to demonstrate the increasing gas passages 402 densities from center to edge. Any other arrangements and patterns of the gas passages 402 may be utilized. The density change concept can also be combined with the gas passage 402 designs to improve center to edge uniformity.

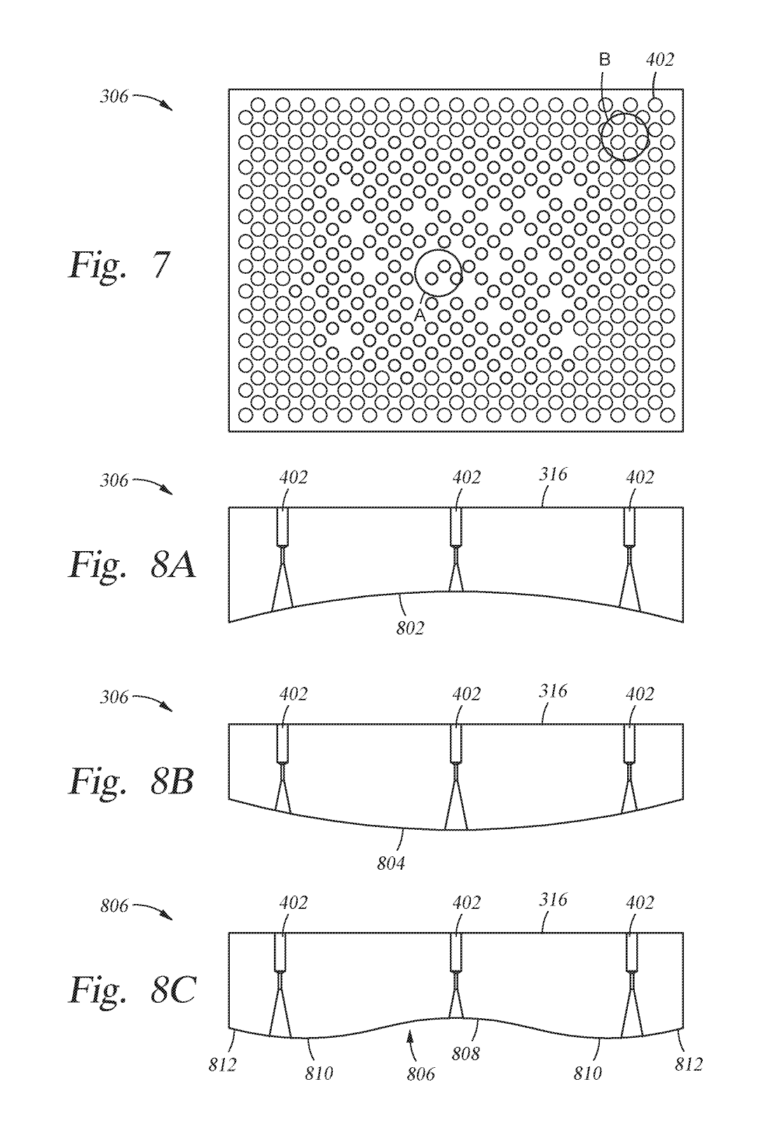

FIGS. 8A-8C are schematic cross sectional side views of the showerhead 306 according to various embodiments described herein. As shown in FIG. 8A, the showerhead 306 includes a first surface 802 facing the substrate support assembly 304, and the second surface 316 opposite the first surface 802. Unlike a planar first surface 314, the first surface 802 may have a curvature, such as a concave surface, as shown in FIG. 8A. With the concave first surface 802, the center region of the first surface 802 is further away from the substrate support assembly 304, or the substrates 208, than the edge region of the first surface 802. In other embodiments, the showerhead 306 has a first surface 804 facing the substrate support assembly 304, and the second surface 316 opposite the first surface 804. The first surface 804 also has a curvature, such as a convex surface, as shown in FIG. 8B. With the convex first surface 804, the center region of the first surface 804 is closer to the substrate support assembly 304, or the substrates 208, than the edge region of the first surface 804. Alternatively, the showerhead 306 has a first surface 806 facing the substrate support assembly 304, and the second surface 316 opposite the first surface 806. The first surface 806 may include a center region 808 that is concave, and a side region 810 that is convex. Thus, the center region 808 and the edge region 812 are further away from the substrates 208 than the side region 810. The showerhead 306 having various designs as shown in FIGS. 8A-8C can improve process and film uniformities.

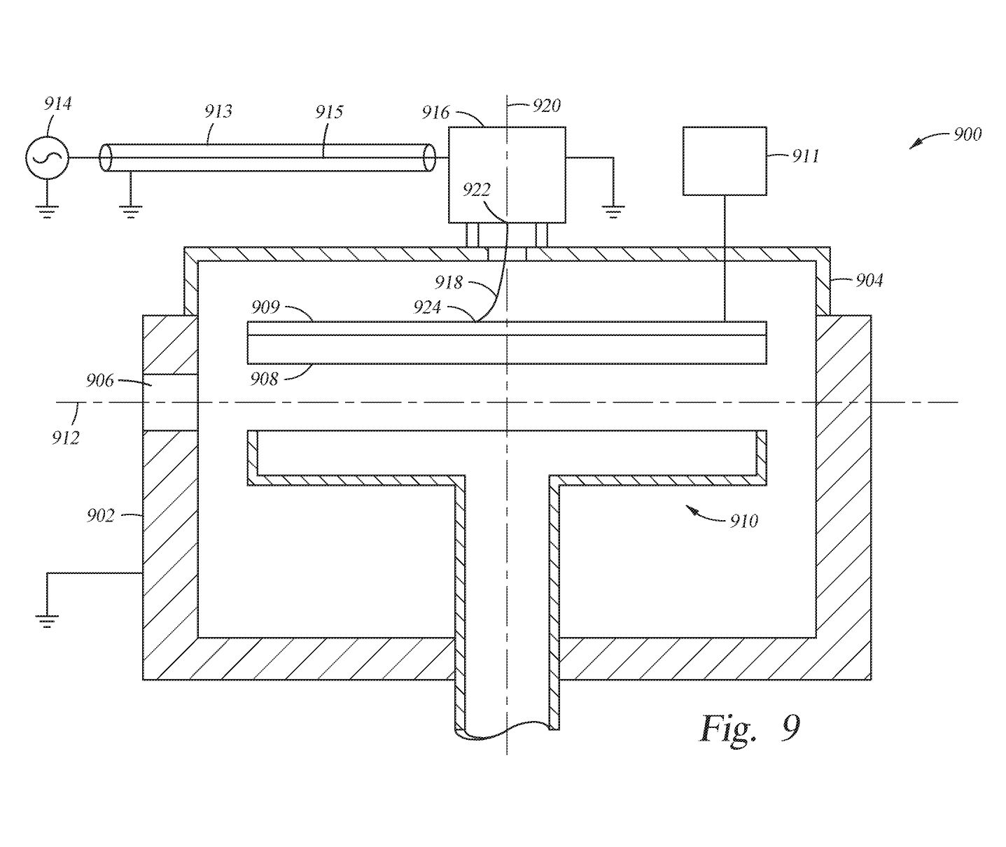

FIG. 9 is a schematic cross sectional view of a process chamber 900 according to embodiments described herein. The process chamber 900 may be a PECVD chamber and may be the process chamber 108 or 114 shown in FIGS. 1A-1D. The process chamber 900 may include a chamber body 902 and a lid 904. A slit valve opening 906 may be formed in the chamber wall for loading and unloading one or more substrates, such as substrates 208 shown in FIGS. 2A-2D. A horizontal axis 912 of the process chamber 900 may extend through the slit valve opening 906. A substrate support assembly 910 may be disposed within the chamber body 902, and a showerhead 908 may be disposed over the substrate support assembly 910. The substrate support assembly 910 may be the substrate support assembly 204, 210, 214, or 222 shown in FIGS. 2A-2D, and the showerhead 908 may be the showerhead 306 shown in FIG. 3. A backing plate 909 may be coupled to a backside of the showerhead 908, and the backing plate 909 may face the lid 904. A gas source 911 may be coupled to the backing plate 909 for delivering one or more process gases into the process chamber 300 via the showerhead 908.

A matching network 916 may be disposed over the lid 904, such as supported by the lid 904, as shown in FIG. 9. The matching network 916 may be electrically connected to a radio frequency (RF) source 914 by a conductor 915. A tube 913 may surround the conductor 915. RF power may be generated by the RF source 914 and applied to the backing plate 909 by a flexible RF feed 918. The flexible RF feed 918 may have a first end 922 electrically coupled to the matching network 916 and a second end 924 electrically coupled to the backing plate 909. The flexible RF feed 918 may be made of a flexible electrically conductive material, such as a copper strip. The flexible RF feed 918 may have a thickness ranging from about 0.2 mm to about 1.5 mm, a length ranging from about 10 cm to about 20 cm, and a width ranging from about 10 cm to about 20 cm. The flexible RF feed 918 may extend from the matching network 916 to the backing plate 909 and may be angled (greater than zero degrees) with respect to a vertical axis 920 of the process chamber 900. The second end 924 of the flexible RF feed 918 may be coupled to different locations on the backing plate 909, due to the flexibility of the flexible RF feed 918, in order to reduce chamber boundary asymmetry (due to the slit valve opening 906) induced plasma non-uniformity.

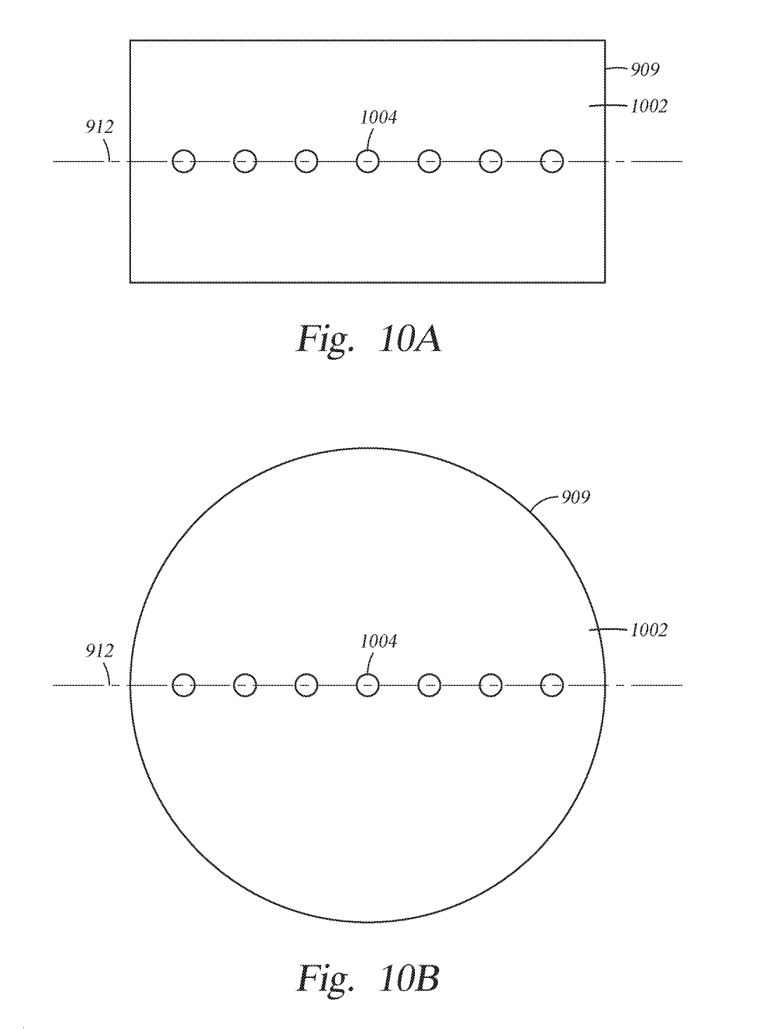

FIGS. 10A-10B are schematic top views of the backing plate 909 according to embodiments described herein. As shown in FIG. 10A, the backing plate 909 may be rectangular and may include a top surface 1002 facing the lid 904 (FIG. 9). A plurality of locations 1004 may be located on the top surface 1002 of the backing plate 909. Each location 1004 may be utilized to secure the second end 924 of the flexible RF feed 918. In one embodiment, each location 1004 is a recess, and a securing device (not shown), such as a screw made of an electrically conductive material, may be utilized to secure the second end 924 of the flexible RF feed 918 in the recess. The plurality of locations 1004 may be aligned along the axis 912 and may be evenly spaced.

Conventionally, an RF feed may connect the matching network and the backing plate, typically the RF feed is at zero degrees with respect to the axis 920. Process chamber asymmetry (e.g., slit valve opening formed on one side of the process chamber) can induce RF path to shift in phase, which causes a high density plasma zone shifting off-center and towards the slit valve. In order to eliminate or minimize the non-uniform plasma caused by the process chamber asymmetry, the flexible RF feed 918 may be electrically connected to the backing plate 909 at a location closer to the slit valve opening 906. By having a plurality of locations 1004 for securing the flexible RF feed 918 on the backing plate 909, plasma uniformity can be fine-tuned. For example, a process chamber, such as the process chamber 900 may have a plasma non-uniformity with the second end 924 of the RF flexible feed 918 coupled to the backing plate 909 at one of the locations 1004. By moving the second end 924 of the RF flexible feed 918 to a different location 1004 on the backing plate 909, plasma non-uniformity can be minimized. The moving of the RF flexible feed 918 may be performed prior to a deposition process.

FIG. 10B is schematic top views of the backing plate 909 according to another embodiment described herein. As shown in FIG. 10B, the backing plate 909 may be circular and having the top surface 1002. Again the plurality of locations 1004 may be formed on the top surface 1002 of the backing plate 909 for securing the second end 924 of the RF flexible feed 918.

The cluster tool including a plurality of process chambers each having a single showerhead not only increases throughput but also improves process and film uniformities. In one embodiment, each process chamber can process four substrates and six process chambers are included in the cluster tool. The cluster tool can process 24 substrates simultaneously while maintaining the process and film uniformities at a reduced cost since one showerhead and RF power source are utilized for each process chamber.

While the foregoing is directed to embodiments of the present disclosure, other and further embodiments of the disclosure may be devised without departing from the basic scope thereof, and the scope thereof is determined by the claims that follow.

1. A cluster tool, comprising:
a transfer chamber;
a loadlock chamber coupled to the transfer chamber; and
a plurality of process chambers coupled to the transfer chamber, wherein each process chamber of the plurality of process chambers comprises:
a chamber wall;
a substrate support assembly disposed within the chamber wall, wherein the substrate support assembly comprises four or more substrate supports; and
a showerhead disposed within the chamber wall, wherein the showerhead is disposed over the four or more substrate supports.

2. The cluster tool of claim 1, wherein the plurality of process chambers includes six process chambers.

3. The cluster tool of claim 1, wherein the showerhead includes a first surface facing the substrate support assembly, and a second surface opposite the first surface.

4. The cluster tool of claim 3, wherein the first surface has a curvature.

5. The cluster tool of claim 4, wherein the first surface is concave.

6. The cluster tool of claim 4, wherein the first surface is convex.

7. The cluster tool of claim 4, wherein the first surface has a first region that is concave and a second region that is convex.

8. The cluster tool of claim 1, wherein the substrate support assembly further comprises a main support and a gap formed between the main support and each substrate support.

9. The cluster tool of claim 1, wherein each process chamber further comprises:
a lid;
a matching network disposed over the lid;
a backing plate coupled to the showerhead; and
a flexible radio frequency feed extending from the matching network to the backing plate, wherein the flexible radio frequency feed is angled with respect to a vertical axis of the process chamber.

10. The cluster tool of claim 9, wherein the backing plate comprises a surface facing the lid and a plurality of locations located on the surface of the backing plate, wherein one of the plurality of locations is connected to the flexible radio frequency feed.

11. A cluster tool, comprising:
a transfer chamber;
a loadlock chamber coupled to the transfer chamber; and
a plurality of process chambers coupled to the transfer chamber, wherein each process chamber of the plurality of process chambers comprises:
a chamber wall;
a substrate support assembly disposed within the chamber wall, wherein the substrate support assembly comprises four or more substrate supports; and
a showerhead disposed within the chamber wall, wherein the showerhead comprises a first surface facing the substrate support assembly, wherein the first surface has a curvature.

12. The cluster tool of claim 11, wherein the plurality of process chambers includes six process chambers.

13. The cluster tool of claim 11, wherein the showerhead further comprises a second surface opposite the first surface.

14. The cluster tool of claim 13, wherein the showerhead further comprises a plurality of gas passages extending from the first surface to the second surface.

15. The cluster tool of claim 14, wherein each gas passage of the plurality of gas passages comprises:
a first bore;
an orifice hole coupled to the first bore; and
a second bore coupled to the orifice hole.

16. The cluster tool of claim 11, wherein each substrate support of the four or more substrate supports is rotatable.

17. The cluster tool of claim 16, wherein each substrate support of the four or more substrate supports is capable of rotating continuously in one direction.

18. The cluster tool of claim 16, wherein each substrate support of the four or more substrate supports is capable of oscillating in opposite directions.

19. A cluster tool, comprising:
a transfer chamber;
a loadlock chamber coupled to the transfer chamber; and
a plurality of process chambers coupled to the transfer chamber, wherein each process chamber of the plurality of process chambers comprises:
a chamber wall;
a substrate support assembly disposed within the chamber wall, wherein the substrate support assembly comprises four substrate supports; and
a showerhead disposed within the chamber wall, wherein the showerhead comprises:
a first surface facing the substrate support assembly;
a second surface opposite the first surface; and
a plurality of gas passages extending from the first surface to the second surface, wherein each gas passage of the plurality of gas passages comprises:
a first bore;
an orifice hole coupled to the first bore; and
a second bore coupled to the orifice hole.

20. The cluster tool of claim 19, wherein the first surface has a first region that is concave and a second region that is convex.
